(19) United States
(12) Patent Application Publication
(10) Pub. No.: US 2026/0180546 A1
(43) Pub. Date: Jun. 25, 2026

(54) SYSTEM FOR DIRECTIONAL SURFACE ACOUSTIC WAVE TRANSMISSION

(71) Applicant: Toyota Motor Engineering & Manufacturing North America, Inc., Plano, TX (US)

(72) Inventors: Taehwa Lee, Ann Arbor, MI (US); Xiaopeng Li, Ann Arbor, MI (US); Ziqi Yu, Ann Arbor, MI (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 18/989,622

(22) Filed: Dec. 20, 2024

(51) Int. Cl. H03H 9/02; H03H 9/25

(52) U.S. Cl. CPC H03H 9/02842; H03H 9/02653; H03H 9/25

(57) ABSTRACT

Systems for directional surface acoustic wave transmission are disclosed herein. In one example, a system includes a transmitter configured to transmit a surface acoustic wave and a receiver configured to receive the surface acoustic wave. A resonant structure may be disposed on the surface of a substrate between the transmitter and receiver and is configured to allow the surface acoustic wave to propagate through the resonant structure towards the receiver and limit a reflection of the surface acoustic wave to propagate through the resonant structure towards the transmitter.

### TECHNICAL FIELD

The subject matter described herein relates, in general, to systems for directional surface acoustic wave transmission.

### BACKGROUND

The background description provided is to present the context of the disclosure generally. Work of the inventor, to the extent it may be described in this background section, and aspects of the description that may not otherwise qualify as prior art at the time of filing, are neither expressly nor impliedly admitted as prior art against the present technology.

A surface acoustic wave is an acoustic wave that travels along the surface of a substrate, with its amplitude decaying exponentially with depth into the substrate. In some instances, surface acoustic waves can be utilized to transmit information by converting electrical signals into mechanical waves that travel along the surface of the substrate. Moreover, a transmitter, such as an interdigital transducer, converts electrical signals into mechanical waves that travel toward a receiver that can convert mechanical waves back into electrical signals.

One advantage of utilizing surface acoustic waves for data transmission is the ability to effectively remove unnecessary signals before being converted back to clean electromagnetic signals. Typically, such surface acoustic wave devices have no directional features, meaning that forward and backward surface wave propagation exhibit the same transmission characteristics. This can sometimes cause transmitted waves to reflect back to the transmitter, thereby degrading signal integrity.

### SUMMARY

This section generally summarizes the disclosure and is not a comprehensive explanation of its full scope or all its features.

In one embodiment, a system includes a transmitter configured to transmit a surface acoustic wave and a receiver configured to receive the surface acoustic wave. A resonant structure may be disposed on the surface of a substrate between the transmitter and receiver and is configured to allow the surface acoustic wave to propagate through the resonant structure towards the receiver and limit a reflection of the surface acoustic wave to propagate through the resonant structure towards the transmitter.

In another embodiment, a resonant structure is configured to allow a surface acoustic wave to propagate through the resonant structure in a first direction and limit a reflection of the surface acoustic wave to propagate through the resonant structure in a second direction.

Further areas of applicability and various methods of enhancing the disclosed technology will become apparent from the description provided. The description and specific examples in this summary are intended for illustration only and are not intended to limit the scope of the present disclosure.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements, or multiple elements may be designed as one element. In some embodiments, an element shown as an internal component of another element may be implemented as an external component and vice versa. Furthermore, elements may not be drawn to scale.

FIG. 1 illustrates an example of a system that includes a resonant structure disposed between the transmitter and receiver that is configured to allow the surface acoustic wave to propagate through the resonant structure towards the receiver and limit a reflection of the surface acoustic wave to propagate through the resonant structure towards the transmitter.

FIGS. 2A-2E illustrate different examples of the resonant structure of FIG. 1.

FIGS. 3A-3E illustrate different performance characteristics of different variations of the resonant structures of FIGS. 2A-2E.

### DETAILED DESCRIPTION

Described are systems and devices for directional surface acoustic wave transmission. As mentioned background section, surface acoustic waves can be utilized to transmit information between a transmitter and receiver. Generally, the transmitter, which may be an interdigital transducer, can convert electrical signals to mechanical waves that travel along the surface to a receiver, which may also be an interdigital transducer that converts the mechanical waves to electrical signals. As mentioned, one advantage of utilizing surface acoustic waves for data transmission is the ability to effectively remove unnecessary signals before being converted back to clean electromagnetic signals.

However, surface acoustic wave devices have no directional features, meaning that forward and backward surface wave propagation exhibit the same transmission characteristics. As such, if the surface acoustic wave is reflected, the reflected wave could interfere with the transmission from the transmitter to the receiver. In some cases, this reflection may happen when the surface acoustic wave comes into contact with the transmitter.

The systems disclosed herein utilize one or more resonant structures that are generally located between the transmitter and the receiver. The resonant structures are configured to allow the surface acoustic wave to propagate through the resonant structure towards the receiver. However, the resonant structure generally limits reflected waves traveling in the other direction from passing through the resonant structure, thereby minimizing the negative impact of reflected surface acoustic waves on data transmission.

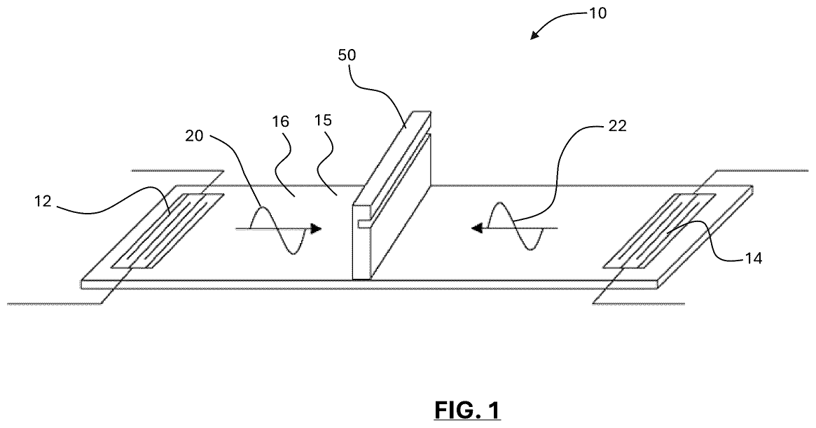

Referring to FIG. 1, illustrated is a system 10 that includes a transmitter 12 and receiver 14 disposed on the surface 16 of the substrate 15. The transmitter 12 can convert electrical signals to surface acoustic waves 20 that can travel on the surface 16 towards the receiver 14, which converts the surface acoustic waves 20 back into electrical signals. As explained beforehand, the surface acoustic wave 20 can essentially be used to transmit information in a mechanical fashion, which can be useful in removing unnecessary noise.

Generally, the transmitter 12 and the receiver 14 may be similar. Moreover, the transmitter 12 and/or the receiver 14 may be interdigital transducers that convert electrical signals into surface acoustic waves 20 and vice versa. In one example, the transmitter 12 and/or the receiver 14 may include two interlocking comb-shaped arrays of metallic electrodes deposited on a piezoelectric substrate, such as quartz or lithium niobate. As to the transmitter 12, when an electrical signal is applied to the electrodes of the transmitter 12, the piezoelectric effect generates mechanical forces, creating surface acoustic waves 20 that travel along the surface 16. In like manner, when the receiver 14 receives the surface acoustic waves 20, the receiver 14 generates electrical signals representative of the received surface acoustic wave 20.

As mentioned, there may be some situations where a reflected surface acoustic wave 22 is generated. In some cases, the reflected surface acoustic wave 22 may be generated by reflections of the surface acoustic wave 20 against one or more components found on the surface 16, such as the receiver 14. The reflected surface acoustic wave 22 may interfere with the surface acoustic wave 20, preventing efficient transmission of information using the surface acoustic wave 20.

In order to minimize the effects of the reflected surface acoustic wave 22, the system 10 includes a resonant structure 50 disposed on the surface 16 of the substrate 15 between the transmitter 12 in the receiver 14. In this example, the resonant structure 50 is shown to extend across the width of the surface 16. However, it should be understood that the resonant structure 50 may only extend across the portion of the width of the surface 16 of the substrate 15. The resonant structure 50 may be attached to the surface 16 using any one of a number of appropriate methodologies, such as adhesives, double-sided tape, bolts, screws, clips, molded fittings, and the like.

The resonant structure 50 may be a structure that naturally amplifies sound waves at specific frequencies, known as its resonant frequencies. When sound waves match these frequencies, the resonant structure 50 vibrates more intensely, amplifying the sound. It has been observed that the resonant structure 50 the controls the transmission of any surface acoustic waves, such as the surface acoustic wave 20 and the reflected surface acoustic wave 22, such that surface acoustic waves preferably propagate in one direction (i.e., from the transmitter 12 to the receiver 14) while the other direction (i.e., from the receiver 14 to the transmitter 12) has minimal wave transmission. By so doing, interference from the reflected surface acoustic wave 22 can be minimized.

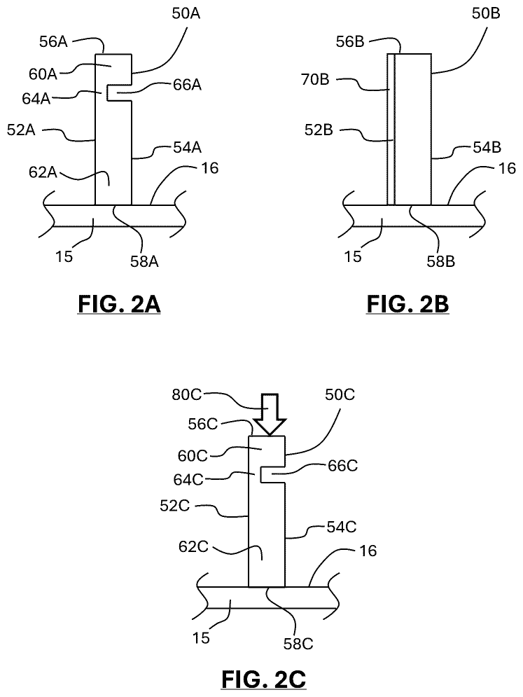

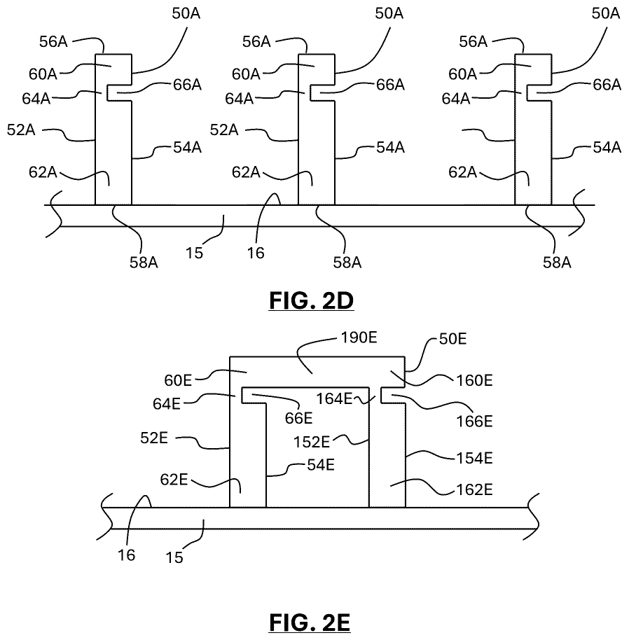

The resonant structure 50 can take a number of different forms, as illustrated in FIGS. 2A-2E. Moreover, referring to FIG. 2A, illustrated is one example of a side view of a resonant structure 50A. In this example, the resonant structure 50 may be a wall that generally extends at least partially across the surface 16 of the substrate 15. Here, the resonant structure 50A includes a top side 56A and a bottom side 58A that is disposed on the surface 16 of the substrate 15. In addition, the resonant structure 50A also includes a first side 52A that generally faces towards the transmitter 12 and a second side 54A that faces towards the receiver 14.

In this example, the resonant structure 50A has an asymmetric geometry that includes a top portion 60A and a bottom portion 62A connected via a connection portion 64A. Notably, the width of the top portion 60A and the bottom portion 62A may be approximately the same, while the width of the connection portion 64A may be less than the width of the top portion 60A and/or the bottom portion 62A. This difference in widths essentially defines a groove 66A that faces toward the receiver 14 and is defined between the top portion 60A, the bottom portion 62A, and the connection portion 64A. Generally, the top portion 60A is smaller than the bottom portion 62A by at least half.

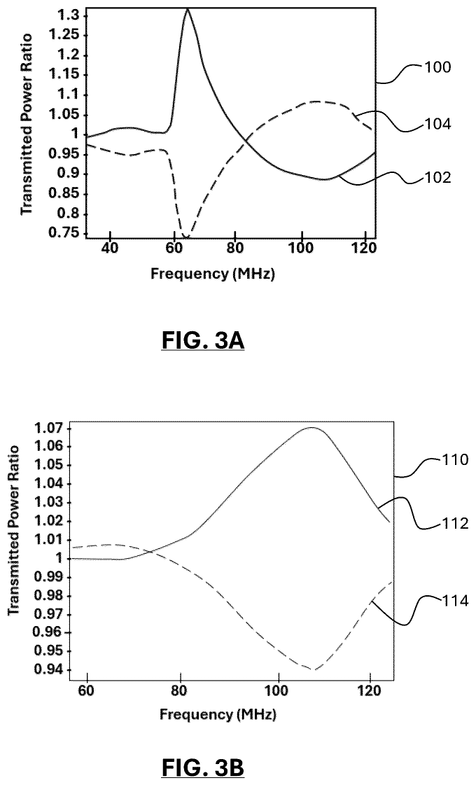

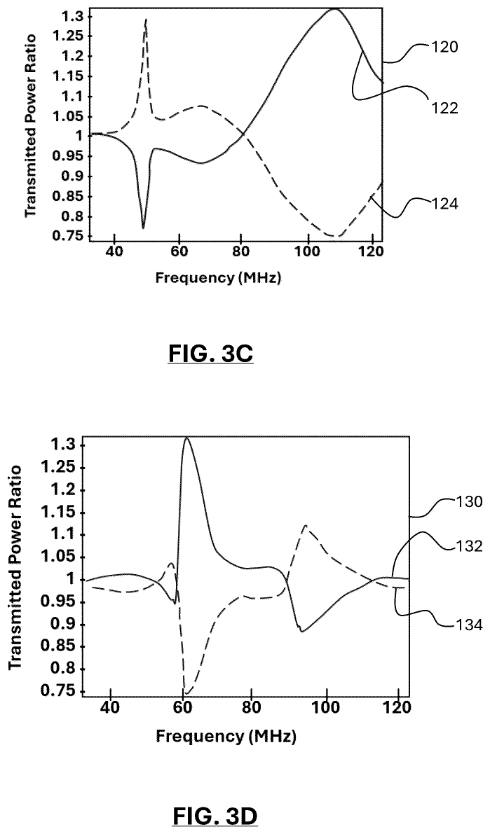

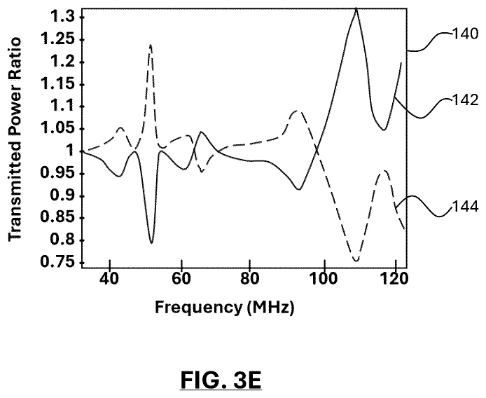

FIG. 3A illustrates a chart 100 of the performance characteristics of the resonant structure 50A. Moreover, the line 102 illustrates the transmission ratio in the direction from the transmitter 12 to the receiver 14. The line 104 illustrates a transmission ratio in the opposite direction, i.e., from the receiver 14 to the transmitter 12. As shown, the largest transmission contrast is observed at 65 MHz. As such, at approximately that frequency, the resonant structure 50A maximizes the transmission of surface acoustic waves in a forward direction (from the transmitter 12 to the receiver 14) but minimizes the transmission of surface acoustic waves in a backward direction (from the receiver 14 to the transmitter 12), thereby minimizing the impact of reflected surface acoustic waves.

Referring to FIG. 2B, illustrated is another example of a resonant structure 50B. Like reference numerals have been utilized to refer to like elements and will not be explained again. In this example, the resonant structure 50B does not have a groove, such as the groove 66A of the resonant structure 50A. Here, the first side 52B, which faces toward the transmitter 12, has a lossy material 70B deposited thereon. The lossy material 70B may have the same material properties as the resonant structure 50B, such as mass density ρ, elastic modulus E, and Poisson's ratio ν, but only added loss (E_{lossy}=E(1+iη)).

FIG. 3B illustrates a chart 110 of the performance characteristics of the resonant structure 50B. The line 112 illustrates the transmission ratio in the direction from the transmitter 12 to the receiver 14. The line 114 illustrates a transmission ratio in the opposite direction, i.e., from the receiver 14 to the transmitter 12. As shown, the largest transmission contrast is observed at 110 MHz. As such, at approximately that frequency, the resonant structure 50B maximizes the transmission of surface acoustic waves in a forward direction (from the transmitter 12 to the receiver 14) but minimizes the transmission of surface acoustic waves in a backward direction (from the receiver 14 to the transmitter 12), thereby minimizing the impact of reflected surface acoustic waves.

Referring to FIG. 2C, illustrated is another example of a resonant structure 50C. Like reference numerals have been utilized to refer to like elements and will not be explained again. The resonant structure 50C is similar to the resonant structure 50A of FIG. 2A. However, the top side 56C is fixed as indicated by the arrow 80C. It was observed that fixing the top side 56C of the resonant structure 50C resulted in different characteristics. Moreover, referring to FIG. 3C, the chart 120 illustrates line 122, which is the transmission ratio in the direction from the transmitter 12 to the receiver 14, and the line 124, which illustrates a transmission ratio in the opposite direction, i.e., from the receiver 14 to the transmitter 12. As can be seen, the largest transmission contrast is shown to be at approximately 110 MHz.

It should be understood that multiple resonant structures may be utilized as well. For example, FIG. 2D illustrates the use of multiple resonant structures. In this example, the multiple resonant structures are the structures illustrated in FIG. 2A. However, other types of multiple resonant structures, such as those illustrated in FIGS. 2B and 2C may also be utilized. Further still, different combinations of different types of resonant structures may also be utilized as well.

FIG. 3D illustrates a chart 130 of the performance characteristics of utilizing multiple resonant structures as illustrated in FIG. 2D. The chart 130 illustrates line 132, which is the transmission ratio in the direction from the transmitter 12 to the receiver 14, and the line 134, which illustrates a transmission ratio in the opposite direction, i.e., from the receiver 14 to the transmitter 12. As can be seen, the largest transmission contrast is shown to be at approximately 60 MHz.

FIG. 2E illustrates another example of a resonant structure 50E. Again, like reference numerals have been utilized to refer to like elements. Here, the resonant structure 50E includes two bottom portions 62E and 162E connected to top portions 60E and 160E via connecting portions 64E and 164E, respectively. The groove 66E is defined between the top portion 60E, the bottom portion 62E, and the connecting portions 64E. In like manner, the groove 166E is defined between the top portion 160E, the bottom portion 162E, and the connecting portions 164E. The resonant structure 50E also has first sides 52E and 152E that face towards the transmitter 12 and second sides 54E and 154E that generally face towards the receiver 14. Here, the top portions 60E and 160E essentially extend toward each other, defining an extension portion 190E, thus resulting in the top portions 60E and 160E being connected to one another.

FIG. 3E illustrates a chart 140 of the performance characteristics of the resonant structure 50E. The chart 140 illustrates line 142, which is the transmission ratio in the direction from the transmitter 12 to the receiver 14, and the line 144, which illustrates a transmission ratio in the opposite direction, i.e., from the receiver 14 to the transmitter 12. As can be seen, the largest transmission contrast is shown to be at approximately 110 MHz.

Detailed embodiments are disclosed herein. However, it is to be understood that the disclosed embodiments are intended only as examples. Therefore, specific structural and functional details disclosed herein are not to be interpreted as limiting but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in the figures. The embodiments are not limited to the illustrated structure or application.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

Aspects herein can be embodied in other forms without departing from the spirit or essential attributes thereof. Accordingly, reference should be made to the following claims rather than to the preceding specification, indicating the scope hereof.

What is claimed is:

1. A system comprising:
a transmitter configured to transmit a surface acoustic wave;
a receiver configured to receive the surface acoustic wave; and
a resonant structure disposed on a surface of a substrate between the transmitter and receiver, the resonant structure configured to allow the surface acoustic wave to propagate through the resonant structure towards the receiver and limit a reflection of the surface acoustic wave to propagate through the resonant structure towards the transmitter.

2. The system of claim 1, wherein the resonant structure has a top portion that is fixed and a bottom portion that is disposed on the surface.

3. The system of claim 1, wherein the resonant structure is a wall that has a first side and a second side, wherein the first side faces the transmitter and the second side faces the receiver.

4. The system of claim 3, further comprising a lossy material disposed on the first side of the wall.

5. The system of claim 3, wherein the wall comprises a bottom portion, a top portion, and a connecting portion that connects the top portion to the bottom portion, wherein the connecting portion has a thickness that is less than a thickness of either the top portion or the bottom portion.

6. The system of claim 5, wherein portions of the connecting portion, the top portion, and the bottom portion define a groove.

7. The system of claim 6, wherein the groove extends along a width of the wall along the second side of the wall.

8. The system of claim 1, wherein the resonant structure comprises a plurality of resonant structures that are configured to allow the surface acoustic wave to propagate through the plurality of resonant structures towards the receiver and limit the reflection of the surface acoustic wave to propagate through the plurality of resonant structures towards the transmitter.

9. The system of claim 8, wherein each of the plurality of resonant structures has top portions that are connected to one another.

10. The system of claim 1, wherein a thickness of the substrate is greater than a wavelength of the surface acoustic wave.

11. A resonant structure configured to allow a surface acoustic wave to propagate through the resonant structure in a first direction and limit a reflection of the surface acoustic wave to propagate through the resonant structure in a second direction.

12. The resonant structure of claim 11, wherein the resonant structure has a top portion that is fixed and a bottom portion that is disposed on a surface of a substrate that the surface acoustic wave travels upon.

13. The resonant structure of claim 12, wherein a thickness of the substrate is greater than a wavelength of the surface acoustic wave.

14. The resonant structure of claim 11, wherein the resonant structure is a wall that has a first side and a second side, wherein the first side faces a source that generates the surface acoustic wave.

15. The resonant structure of claim 14, further comprising a lossy material disposed on the first side of the wall.

16. The resonant structure of claim 15, wherein the wall comprises a bottom portion, a top portion, and a connecting portion that connects the top portion to the bottom portion, wherein the connecting portion has a thickness that is less than a thickness of either the top portion or the bottom portion.

17. The resonant structure of claim 16, wherein portions of the connecting portion, the top portion, and the bottom portion define a groove.

18. The resonant structure of claim 17, wherein the groove extends along a width of the wall along the second side of the wall.

19. The resonant structure of claim 11, wherein the resonant structure comprises a plurality of resonant structures that are structure configured to allow the surface acoustic wave to propagate through the resonant structure in the first direction and limit the reflection of the surface acoustic wave to propagate through the resonant structure in the second direction.

20. The resonant structure of claim 19, wherein each of the plurality of resonant structures have top portions that are connected to one another.
